(19) United States
(12) Patent Application Publication
(10) Pub. No.: US 2004/0195516 A1
(43) Pub. Date: Oct. 7, 2004

(54) Indium features on multi-contact chips

(76) Inventors: Brian Matthews, Pasadena, CA (US); Stephen M. Schindler, Pasadena, CA (US); Aleksey E. Bolotnikov, S. Setauket, NY (US)

Correspondence Address: FISH & RICHARDSON, PC, 12390 EL CAMINO REAL, SAN DIEGO, CA, 92130-2081, US

(21) Appl. No.: 09/933,349

(22) Filed: Feb. 23, 2001

(51) Int. Cl. G01T 1/24

(52) U.S. Cl. 250/370.13; 250/370.09; 250/370.08; 427/124

(57) ABSTRACT

A device comprising a pixilated semiconductor detector or VLSI chip having plurality of individual indium bumps arrayed on a surface of the detector, wherein the indium bumps are in electrical contact with the surface and are situated in defined locations on the surface is provided. Additionally, a hybrid detector comprising a pixilated detector in electrical contact with a VLSI chip, wherein electrical contacts formed from indium metal are made between the pixels of the semiconductor and regions on the VLSI chip corresponding thereto is provided. In another embodiment, a method of forming electrical contacts on a pixilated detector comprising the steps of constraining a shadow mask having an array of holes in predetermined locations above a surface on the detector, aligning the mask above the detector, and evaporating indium metal under vacuum through holes in the mask onto the surface of the detector to form the contacts is described.

### CROSS-REFERENCE TO RELATED APPLICATIONS

The present application claims benefit of U.S. Provisional Application No. 60/184,502, filed Feb. 23, 2000.

### STATEMENT REGARDING FEDERALLY SPONSORED RESEARCH AND DEVELOPMENT

The invention described herein was made in the performance of work under a NASA contract, and is subject to the provisions of Public Law 96-517 (U.S.C. 202) in which the contractor has elected to retain title.

### FIELD OF THE INVENTION

The present invention relates to semiconductor detectors and chips for use in imaging devices and also to methods for forming indium features on a surface of such a detector or chip.

### BACKGROUND AND SUMMARY

Pixilated multi-contact detectors employing semiconductors, such as Si, Ge, HgI, CdTe, and CdZnTe, with readout chips are currently under development in many research laboratories. These detectors are key components in imaging systems with medical, industrial, and scientific applications. For example, the CdZnTe (CZT) semiconductor detector is a device for the imaging and spectroscopy of hard X-rays and low-energy gamma-rays. The CZT detector demonstrates improved room temperature spatial and energy resolution of X-rays. CZT multi-contact detectors are being developed, in one instance, for use in medical scanners and homographs. Typically, each imagining system will require many thousands of individual CZT detectors.

Several technological problems need to be solved in the path towards final commercialization of multi-contact detectors. One key issue is associated with the detailed steps leading to the electrical coupling of the detector to a corresponding readout chip.

Processes using Pb/Sn solder bumps are usually not used for pixilated semiconductor detectors. The processing of the solder bumps during flip-chip bonding requires heating the detector to reflow the solder at high temperatures. These temperatures can be high enough to cause damage to the detector. At temperatures above about 105° C. damage begins to occur. For example, a eutectic Pb/Sn solder (40% Pb and 60% Sn) must be heated to approximately the solder melting point, 183° C., to reflow the solder.

In contrast, indium flip-chip techniques typically can be accomplished at room temperature. A critical, process-intense step in the coupling of a CZT detector to a readout chip is the initial indium bump deposition on the CZT detector contacts. An existing wet lithographic process for forming indium contacts on CZT detectors involves depositing small indium bumps through an evaporation technique onto both the CZT and the readout chip contacts. Bump height in the wet lithographic process is limited by the maximum obtainable photoresist thickness to about 5 to about 12 μm. The width of the photolithographic bumps is about 10 to about 30 μm. The detector and corresponding readout chip are then coupled together using well-known flip-chip bonding technology. During indium flip-chip bonding a permanent electrical contact is made through the indium bumps by precisely aligning and then pressing together the corresponding indium bumps on the CZT and the readout chip until the bumps are securely attached to one another (i.e., by cold-welding corresponding bumps to each other).

The wet photolithographic process is used to pattern the indium bump locations on the CZT surface before actual indium evaporation. This process involves multiple steps, which can include: spinning the photoresist layers on the CZT surface, baking solvents out of the photoresist, exposing the photoresist through a patterned mask, developing the photoresist to dissolve away unwanted regions, depositing indium on the surface of the CZT contacts using the remaining photoresist as a barrier, and finally lifting the unwanted metal.

The CZT surface is physically and chemically delicate. The deposition of indium bumps using the wet photolithographic processes as described above inherently requires substantial handling of the chip and introduces possible chemical incompatibilities. Any type of chemical residue on the surface of the detector may increase leakage current.

A further drawback of the standard wet photolithographic technique is the problem of edge bead generation that occurs when the photoresist is spun onto a detector and the edges of the detector collect excess photoresist thereby causing a thicker region to form. This edge region cannot be patterned, does not have indium contacts, and therefore represents a dead space. The lack of indium contacts at the edges may pose a problem when CZT detectors are arrayed together to form a larger area detector, as required in many applications. In an array, a dead-space exists at each detector-detector interface, resulting in loss of effective overall detector area. One method of removing this dead space is to trim the edges of each CZT chip after indium deposition. However, the trimming procedure introduces considerable risk to the detector at the end of the processing cycle through substrate contamination and breakage. The resulting low yield of detectors may increase the cost of manufacture.

U.S Pat. No. 5,952,646 describes a semiconductor imaging device that includes a radiation detector semiconductor substrate connected to a readout substrate by means of low-temperature solder bumps. The low-temperature solder allows a detector chip to be electrically connected to the readout chip. However, processes that require reflow of the solder bump produce wider bumps. This can be disadvantageous not only do narrower electrical connections reduce electronic noise but they also allow more bumps to be formed over a smaller area, thus decreasing pitch advantageously. Additionally, solder-bumps form electrical connections in hybrid detectors that have a tendency to cold fracture when the hybrid is cooled to temperatures such as −15° to −20° C. for applications that require increased spatial and energy resolution.

According to the present invention, there are provided pixilated semiconductor detectors with predetermined patterned arrays of indium bumps, ranging from about 15 to about 100 μm high, disposed upon a surface of the detector. In another embodiment of the invention, a pixilated VLSI chip is provided with such a patterned array of about 15 to about 100 μm indium bumps disposed on a surface of the chip. The indium bumps allow the detector to be bump-bonded to a chip having a similar array of indium bumps disposed upon a surface using well-known flip-chip technology. A further embodiment of the invention provides a hybrid detector having of a pixilated semiconductor detector in electrical contact with a VLSI chip wherein the electrical contacts are formed from the mating of corresponding indium bumps on the detector and the chip and the surfaces of the detector and the chip are separated by a distance of about 15 to about 100 μm.

The present invention further provides a method for producing indium bumps disposed upon a semiconductor substrate surface using a mechanical shadow mask. The method is capable of producing a pattern of precisely arrayed features having a height of about 10 to about 200 μm. The corresponding width of the bumps produced depends on the size of the apertures in the mask, and can be as narrow as 10 μm. Advantageously, the bumps are narrower at the top than they are at the base of the bump where the bump contacts the surface of the chip. Bumps that are narrow at the top produce cylinder-shaped contacts between the detector and chip after cold-welding. The shadow mask consists of a thin sheet with a precisely patterned array of holes corresponding to the desired indium bump pattern. The mask is mechanically held above the substrate surface, aligned with the substrate, and evaporated indium metal is deposited through the mask onto the substrate surface. The distance between the mask and the substrate surface determines the height of the resulting bumps.

### BRIEF DESCRIPTION OF THE DRAWINGS

FIG. 1 is a schematic of a mechanical shadow mask used in one embodiment of the invention to produce a regular array of precisely-aligned indium bumps on a pixilated semiconductor detector or chip.

FIG. 2 is a schematic illustration of the alignment features of the shadow mask of FIG. 1.

FIG. 3 is an illustration of two views, a view from above and a cut-away side view, of a fixture used to precisely align a shadow mask above a pixilated detector or chip.

### DETAILED DESCRIPTION

The present invention provides pixilated detectors and chips with indium bumps disposed upon a surface. The indium bumps are of an advantageous size and shape that reduces electronic noise in a hybrid device created via bump-bonding a semiconductor detector to a readout chip. The bumps may be taller than those that can be produced using conventional wet photolithographic techniques and narrower and more robust at low temperatures than those produced using low-temperature solder reflow techniques. The height and width of the metal bump may be of key importance in applications such as CZT detectors since the capacitance between the CZT contacts and the ground surface of the readout chip varies as a function of bump height. Electronic noise is a significant limiting factor in the detector's ability to image radiation. Higher bump heights may lower the capacitance and the lower the electronic noise. A metal bump height of more than about 20-30 μm may reduce the electronic noise to a minimum.

Specifically, the present invention provides either a pixilated semiconductor detector or VLSI chip having plurality of individual indium bumps arrayed on a surface of the detector or chip, wherein the indium bumps are in electrical contact with the surface, are situated in predetermined locations on the surface, and are about 15 to about 100 μm high. In a further embodiment of the invention, the semiconductor is a Si, Ge, HgI, and CdTe, or CdZnTe detector. In a preferred embodiment, the indium bumps on a detector or chip are at least 20 μm tall. Preferably all the bumps are substantially (to within ±10%) the same height to optimize the formation of electrical contacts during flip-chip bonding.

The invention additionally provides a hybrid detector comprising a pixilated detector in electrical contact with a VLSI chip, wherein electrical contacts are made between the pixels of the semiconductor detector and corresponding regions on the VLSI chip, and the electrical contacts are formed from indium metal, and wherein the surfaces of the pixilated detector and the VLSI chip are separated by about 25 to about 100 μm.

In another embodiment of the invention, a method of forming tall indium bumps in defined locations on a surface of a detector or chip is provided. This method is capable of forming any number of bumps from one to a few thousand. Additionally, the method can be used to form bumps on the surface of one chip or on multiple chips at once (i.e., a wafer). Applying this technique to multiple chips maybe used in VLSI chip processing in which arrays of bumps can be formed on a sheet of chips which are then mechanically cut apart. It may reduce complexity, processing time, and manufacturing costs as compared to wet photolithographic processes.

Specifically, the invention provides a method of forming electrical contacts on a pixilated detector or chip comprising constraining a mask having a pattern of circular apertures corresponding with the pixilated regions of the detector or chip about 10 to about 200 μm above a surface on the detector or chip, aligning the mask above the pixilated detector or chip, and evaporating indium metal under vacuum through apertures in the mask onto the surface of the detector or chip. In a preferred embodiment, the mask is held about 10 to about 100 μm above the detector or chip. The indium bumps formed from this method are wider at the base where the bump contacts the detector than they are at the apex. The width of the bumps produced is a function of the size of the aperture in the mask and can be as small as 10 μm. In a preferred embodiment, the apertures in the mask are 50 μm in diameter and the resulting bumps are only slightly (about 0 to 10%) larger in diameter.

A detector with indium bumps disposed upon a surface can further be bump-bonded to a readout chip that has indium bumps similarly positioned upon a surface. Bump-bonding can be accomplished with flip-chip procedures in which the bumps on a detector are aligned with the bumps on a corresponding readout chip and pressed together. At room temperature the indium bumps will flow together creating an electrical connection, through a process called cold-welding. The separation between the surfaces of the resulting hybrid device is a function of the degree to which the detector and the chip are compressed. A detector having 50 μm high bumps is cold-welded to a chip with 50 μm high bumps resulting in a hybrid device in which the surfaces of the detector and chip are separated by at most 90 μm and more preferably 50 μm. In another preferred embodiment, the shadow mask has larger openings disposed around the periphery of the pixel apertures which create features when indium is evaporated through the mask that increase the mechanical stability of a bump-bonded hybrid detector. Optionally, the resulting device can be further mechanically stabilized by applying an adhesive to a region between the detector and the chip.

The shadow mask can be fabricated from thin materials, such as metal foils, glass, or any rigid material with a coefficient of expansion less than 10×10⁻⁶. In one embodiment, a nickel-cobalt mask with a thickness of 0.002 inches (50 μm) and a flatness of 0.0001 inches (2.5 μm) or better is used. Patterned masks can be readily prepared by any standard mask fabrication procedure such as photolithography or laser etching.

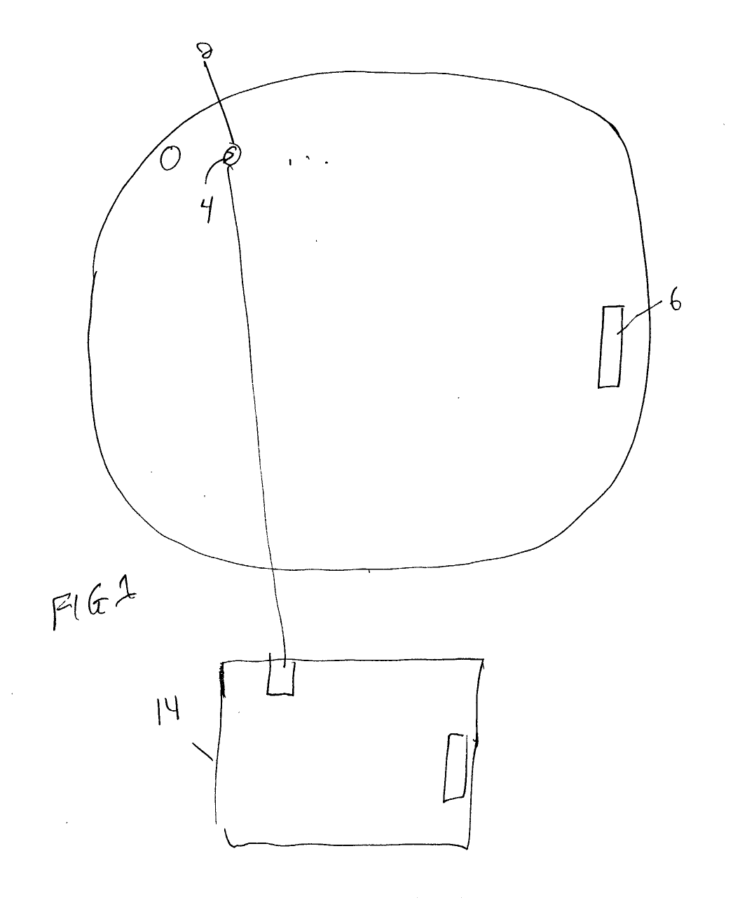

FIG. 1 is a shadow mask used in an embodiment. The mask depicted has sixty-four circular apertures 2 disposed at predetermined positions corresponding to an 8×8 array of pixels found on a typical CZT detector. The mask is held above the surface of the detector or chip and indium is deposited through the apertures 2 onto the surface of the detector or chip. Larger-mechanical bumps are created during this deposition process by mechanical bump openings 4 supplied along the periphery of the 8×8 array of apertures 2. The optional mechanical bump openings 4 provide the resulting bump-bonded detector-readout device with greater mechanical stability. An alignment slot 6 is provided to align the mask with the detector or chip 14.

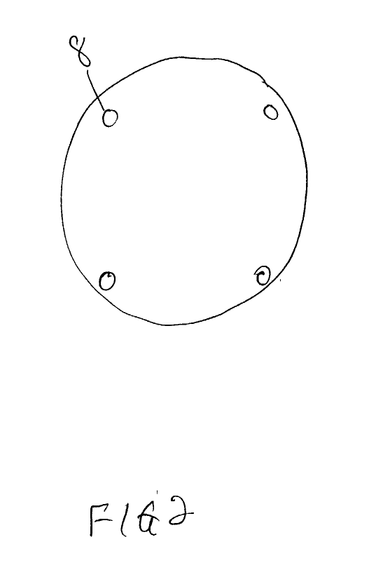

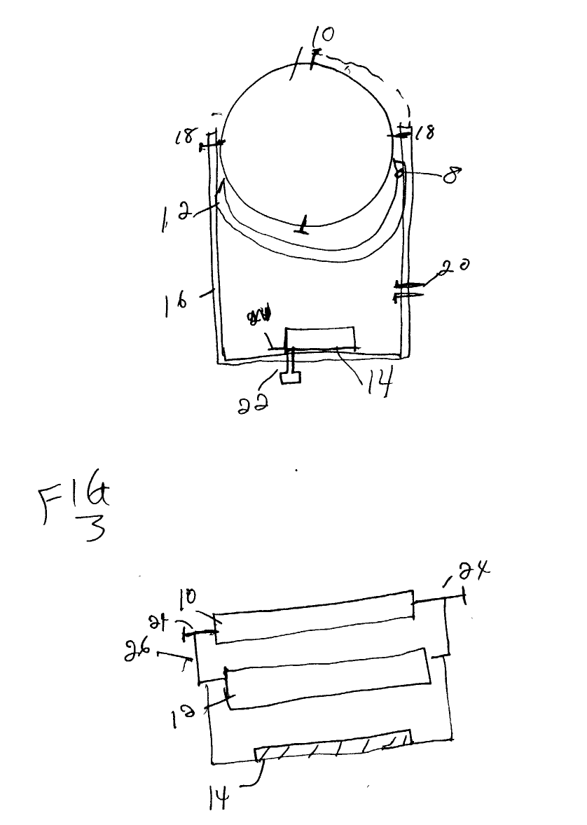

FIG. 2 is a reduced view of the shadow mask of FIG. 1 showing four mounting holes 8 which are used to align the mask with the detector or chip 14 in the alignment fixture of FIG. 3. The four mounting holes 8 create a bolt circle with a diameter of 1.444 inches (3.67 cm). The mounting holes 8 each have a diameter of 0.0094 inches (0.024 cm).

FIG. 3 shows an alignment fixture used in one embodiment of the invention to precisely align a shadow mask with a detector or chip and to hold the mask and the detector aligned during the evaporation process in which indium bumps are grown on the detector or chip's surface. The top diagram shows a view from above the fixture and the bottom diagram is a cut-away side view of the same fixture. In the top diagram, a stainless steel disc 10 is placed over the shadow mask 12 and joined to the base 16 which holds a detector or chip 14. Four captive screws 18 join the disc 10 to the base 16. Screws placed in the mounting holes 8 attach the shadow mask 12 to the disc 10. A vacuum inlet 20 is supplied.

In the bottom diagram of FIG. 3, the base 16 contains a thumb wheel 22 which is used for z-axis alignment. The thumb wheel 22 allows the detector or chip 14 to be moved toward the shadow mask 12. A top plate 24 connects the disc 10 to the commercial mask aligner 26 via four screws 24. The shadow mask 12 is held above the detector or chip 14 so that the shadow mask 12 and the detector or chip 14 are not in contact.

### EXAMPLE 1

In the following example, indium bumps are grown on a pixilated CZT detector. The CZT substrate is obtained with an 8×8 array of pixels and precision alignment marks on the CZT surface. The pixilated CZT detector is mounted on the base 16 of the alignment fixture (fixture) (FIG. 3) and constrained in place with a compatible adhesive agent, such as “photoresist”, that is placed on the non-pixilated CZT surface. The photoresist is then cured by heating at 95° C. for 2 minutes. A clean Teflon shim of the same thickness as the desired height of the indium bumps (i.e., the shim had a thickness of between about 10 to 100 μm), is placed on top of the CZT. The shadow mask, containing an 8×8 array of holes (FIG. 1), is then mounted into the fixture's shadow mask constraining ring (disc 10) (using mounting holes 8) and constraining ring is locked into place with screws 18 above the CZT detector. The fixture's height adjustment feature, the thumb wheel 20, is then employed to precisely adjust the height of the CZT, so that the CZT, Teflon shim, and shadow mask are in contact. This arrangement is locked into place with mechanical hardware and the shadow mask constraining ring along with the Teflon shim are removed. The shim is removed and the shadow mask retaining ring (disc 10) is then replaced on the fixture and locked into place. The resulting gap between the CZT and the shadow mask has a fixed precision value corresponding to the desired bump height.

The fixture is placed in a standard commercial mask aligner (model Karl Suss MJB-3 IR) 26 and locked into place using a vacuum chuck. The alignment marks on the shadow mask are then aligned with those on the CZT using a microscope and precision horizontal (x- and y-axes) alignment screws on the commercial mask aligner 26. A second vacuum chuck on the fixture is employed to maintain the relative alignment between the CZT and the shadow mask until mechanical hardware locks the alignment into place. The fixture is then removed from the commercial mask aligner and placed in an indium evaporation chamber and locked in place on the chamber cooling plate. The evaporation chamber is evacuated to about 10⁻⁶ mmHg, cooled to about −25° C. and the indium is deposited through the holes in the shadow mask onto the CZT surface.

The fixture is taken out of the evaporation chamber. The mask retaining ring with the shadow mask attached is then removed from the fixture. The chip holding section of the fixture is removed from the remaining fixture and placed in an acetone bath to dissolve the adhesive from the bottom surface of the chip.

### EXAMPLE 2

In another embodiment indium bumps are grown on a VLSI chip. The equipment and procedure are substantially the same as described in Example 1. A shadow mask is obtained with an array of holes matching the pixel pattern of the VLSI chip. The chip 14 and shadow mask 12 are constrained in the alignment fixture (FIG. 3), a precisely measured space is created between the mask and the chip with a Teflon spacer, the fixture is placed in a commercial mask aligner 26 (model Karl Suss MJB-3 IR), and the mask is precisely horizontally aligned above the VLSI chip. The alignment fixture is removed from the commercial mask aligner 26 and placed in an indium evaporation chamber and indium is deposited through the mask onto the chip's surface. As in Example 1, height of the bumps grown on the VLSI chip is determined by the size of the Teflon spacer used.

### EXAMPLE 3

Using existing flip-chip technology, the CZT detector and the VLSI chip are bump bonded together to form a hybrid detector. A standard flip-chip alignment device is used for the process. A small (about 1 mm×1 mm) drop of a silicon adhesive is then placed on two or three of the corners of the resulting bump-bonded chip to provide additional mechanical strength. A silicon adhesive is used because it cures at room temperature, does not outgas contaminants and provides a joint that is resilient to shocks and vibrations. A silicon adhesive that is typically used is RTV 167 made by General Electric.

What is claimed is:

1. A solid-state detector comprising:
a pixilated semiconductor detector having plurality of individual indium bumps arrayed on a surface of the detector, wherein the indium bumps are in electrical contact with the surface and are situated in defined locations on the surface, and the indium bumps have a height of between 15 to about 100 μm.

2. The solid-state detector of claim 1 wherein the indium bumps have a height of between 20 to about 70 μm.

3. The solid-state detector of claim 1 wherein the pixilated detector is selected from the group consisting of Si, Ge, HgI, CdTe, and CdZnTe semiconductors.

4. A readout chip comprising VLSI chip having a plurality of individual indium bumps arrayed on a surface of the chip, wherein the indium bumps are in electrical contact with the surface and are situated in defined locations on the surface, and the indium bumps have a height ranging from 15 to 100 μm.

5. A hybrid detector comprising a pixilated detector in electrical contact with a VLSI chip, wherein the detector and the VLSI chip each have a surface with regions adapted to forming electrical contacts, and wherein electrical contacts formed from indium metal are made between the pixels of the semiconductor detector and regions on the VLSI chip corresponding thereto, and wherein the surfaces of pixilated detector and the VLSI chip are separated by about 15 to about 100 μm.

6. A method of forming predetermined electrical contacts on a detector comprising:
constraining a shadow mask having an array of holes in desired locations 10 to 100 μm above a surface on the detector, aligning the mask above the detector, and evaporating indium metal under vacuum through holes in the mask onto the surface of the detector to form the contacts.

7. The method of claim 6, further comprising the step of bump-bonding the detector to readout chip that has indium bumps similarly positioned upon a surface.

8. A method of forming predetermined electrical contacts on a chip comprising:
the steps of constraining a shadow mask having an array of holes in desired locations about 10 to about 100 μm above a surface on the chip, aligning the mask above the chip, and evaporating indium metal under vacuum through holes in the mask onto the surface of the chip to form the contacts.
